(19) United States
(12) Patent Application Publication
(10) Pub. No.: US 2006/0180821 A1
(43) Pub. Date: Aug. 17, 2006

(54) Light-emitting diode thermal management system

(75) Inventors: Xue-Jan Fan, Chandler, AZ (US); Peng Xu, Danbury, CT (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/562,528

(22) PCT Filed: Jun. 21, 2004
(86) PCT No.: PCT/IB04/02055

§ 371 Date: Dec. 28, 2005

Related U.S. Application Data
(60) Provisional application No. 60/483,768, filed on Jun. 30, 2003.

(51) Int. Cl. H01L 33/00

(52) U.S. Cl. 257/98

(57) ABSTRACT

A device 101 for thermal management of an LED 120 employs a heatsink 160, a substrate 111, a trace layer 130 and a via 180. The via 180 includes a sidewall 182 defining a channel 181 extending through substrate 110. The channel 181 is beneath the trace layer 130 and above the heatsink 160 to transfer any heat applied to the trace layer 130 by the LED 120 to the heatsink 160.

In general, the invention relates to light-emitting diode (“LED”) light sources. More specifically, the invention relates to thermal management of an LED system.

Artificial light generated utilizing an LED light source also produces a large amount of heat. Circuit boards, by their very nature, do not provide adequate thermal transfer rates and therefore thermal buildup occurs within the LED as well as other components in close proximity to the LED. Thermal buildup within the LED light source is harmful to the useful life of the LED light source.

To resolve the thermal buildup issue, conventional LED light source assemblies typically include a circuit board having a hole with the LED mounted therein. The LED extends through the hole in the circuit board with a light emitting portion or lens portion of the LED extending from one of the surfaces of the circuit board, and a heat sink portion extending from the opposite surface. The heat sink portion of the LED is attached to a heat spreader. The present invention advances the art of light emitting diode thermal management.

One form of the invention includes a device for thermal management of an LED including a heatsink, a substrate overlying the heatsink, and a trace layer overlying the substrate. The device further includes a via extending through the substrate, the via in thermal communication with the trace layer and the heatsink to transfer to the heatsink any heat applied to the trace layer by the LED.

A second form of the invention includes a device for thermal management of an LED including a heatsink, a flexible substrate overlying the heatsink, and a trace layer overlying the flexible substrate. The flexible substrate is in thermal communication with the trace layer and the heatsink to transfer to the heatsink any heat applied to the trace layer by the LED.

The foregoing forms and other forms, features and advantages of the invention will become further apparent from the following detailed description of the presently preferred embodiment, read in conjunction with the accompanying drawings. The detailed description and drawings are merely illustrative of the invention rather than limiting, the scope of the invention being defined by the appended claims and equivalents thereof.

FIG. 1 illustrates a cross-sectional side view of a LED light source assembly utilizing a flexible substrate in accordance with one embodiment of the present invention;

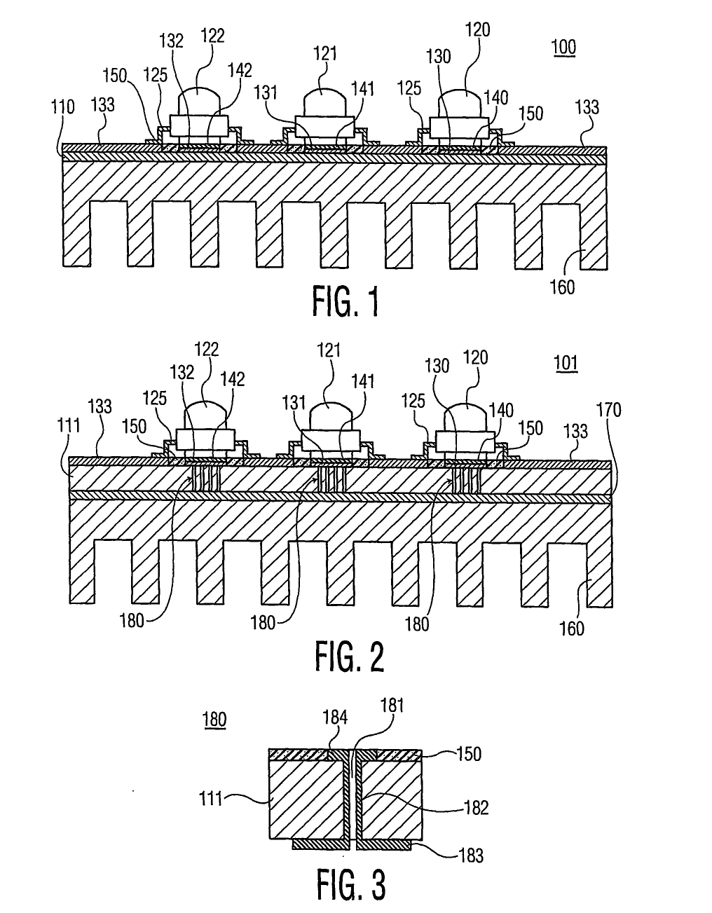

FIG. 2 illustrates a cross-sectional side view of an LED light source assembly utilizing a standard substrate and thermal vias in accordance with another embodiment of the present invention;

FIG. 3 illustrates a cross-sectional side view detailing the thermal via portion of an LED light source assembly of FIG. 2 in accordance with one embodiment of the present invention;

FIG. 4 illustrates a cross-sectional side view of an LED light source assembly utilizing a flexible substrate including thermal vias in accordance with one embodiment of the present invention;

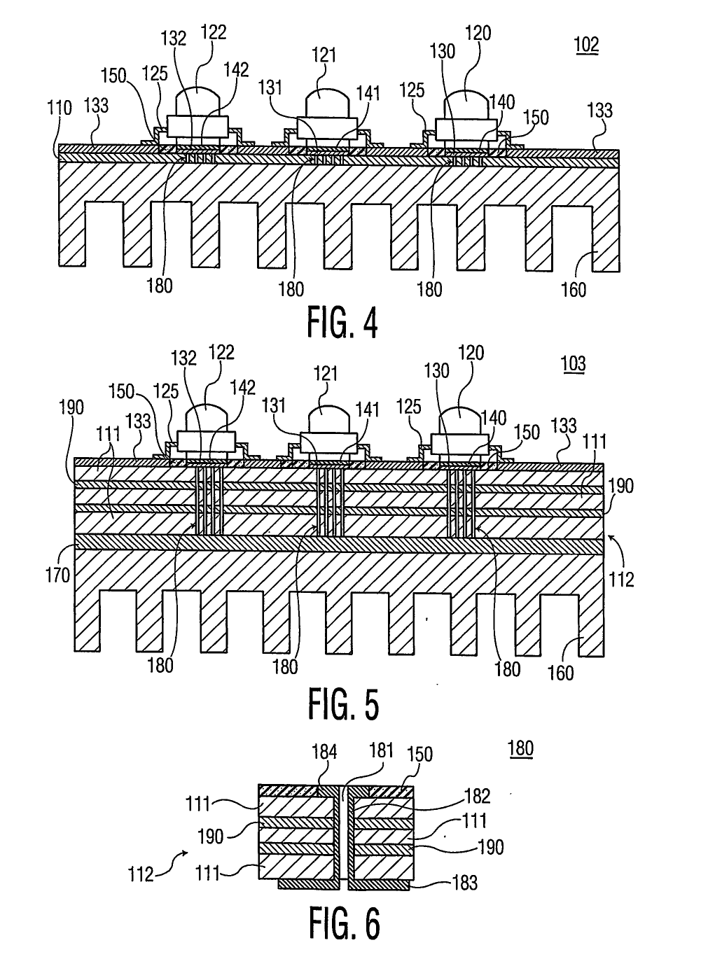

FIG. 5 illustrates a cross-sectional side view of an LED light source assembly utilizing a multi-layered substrate including thermal vias in accordance with one embodiment of the present invention;

FIG. 6 illustrates a cross-sectional side view detailing the thermal via portion of a LED light source assembly of FIG. 5 in accordance with one embodiment of the present invention; and

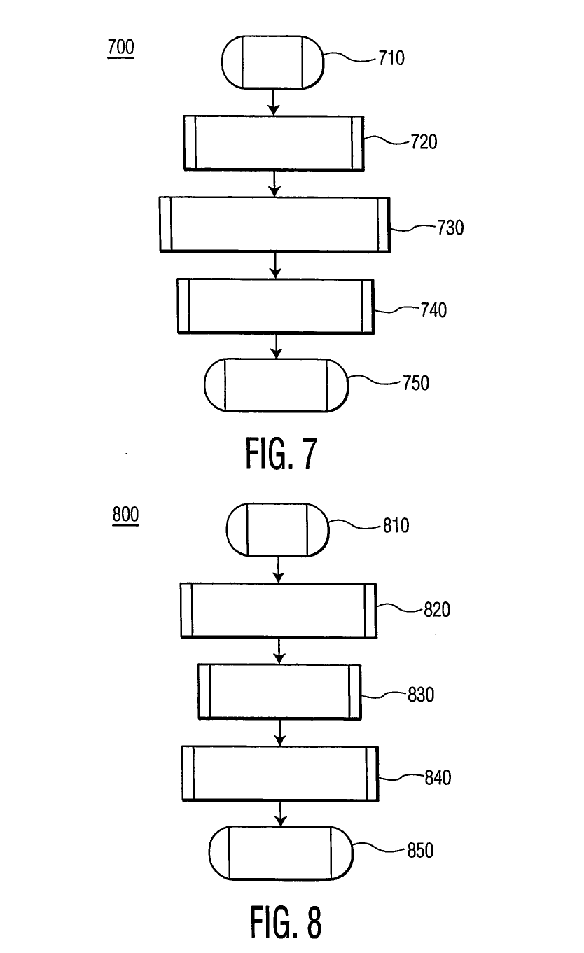

FIG. 7 illustrates a method for fabricating a device for thermal management of an LED in accordance with one embodiment of the present invention;

FIG. 8 illustrates a method for fabricating a device for thermal management of an LED in accordance with another embodiment of the present invention; and

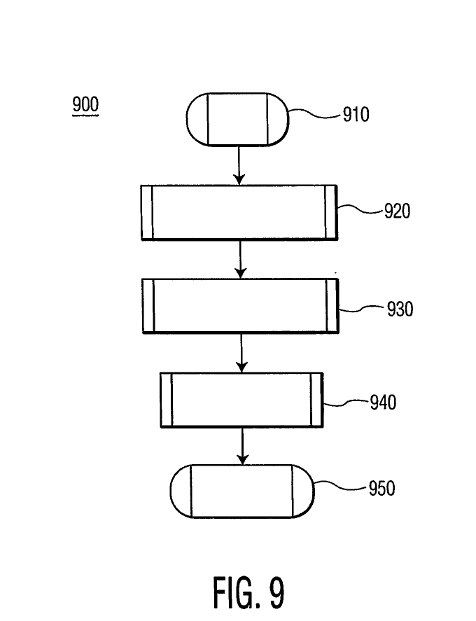

FIG. 9 illustrates a method for fabricating a device for thermal management of an LED in accordance with yet another embodiment of the present invention.

FIG. 1 illustrates a cross-sectional side view of LED light source assembly 100. LED light source assembly 100 includes a flexible substrate 110, light emitting diodes 120-122, trace layers 130-133, pads 140-142, insulation layers 150, and heatsink 160. LED light source assembly 100 may include additional components not relevant to the present discussion.

In FIG. 1, flexible substrate 110 includes two surfaces, a top surface and a bottom surface. The top surface of flexible substrate 110 includes trace layers 130-133 overlying the top surface and insulation layers 150 overlying the top surface. Trace layers 130-132 provide mounting points for pads 140-142 and LEDs 120-122. Trace layers 133 provide one or more paths for current to flow within flexible substrate 110. Insulation layers 150 restrict current flow to particular areas of flexible substrate 110, such as, for example trace layers 130-132 and associated pads 140-142. Insulation layers 150 allow components such as LEDs 120-122 to be thermally coupled to flexible substrate 110 for heat transfer. Insulation layers 150 may be implemented as any suitable insulation material, such as, for example solder mask and air. The bottom surface of flexible substrate 110 is operably coupled to heatsink 160.

Flexible substrate 110 is a flexible mounting platform that is designed to allow components operably coupled to flexible substrate 110 to function as designed. In one embodiment, flexible substrate 110 is produced including one or more trace layers 130-133 overlying flexible substrate 110, and one or more pads 140-142 overlying trace layers 130-133. In an example, flexible substrate 110 is produced as a flex tape having a thickness of less than 50 micro meters (μm) with one or more trace layers 130-133 overlying flexible substrate 110 and one or more pads 140-142 overlying trace layers 130-133. Flexible substrate 110 can be implemented as any suitable flexible substrate, such as, for example single-layer flex available from COMPASS Technologies Co. Ltd. of Shatin, Hong Kong.

Light emitting diodes 120-122 are light emitting components that are mounted to pads 140-142 and are operably coupled to one or more trace layers 130-133 so as to be in electrical communication with the trace layers, such as, for example by utilizing one or more connectors 125. Each light emitting diode 120-122 is mounted to an associated pad 140-142 utilizing any suitable mounting material, such as, for example solder or thermally conductive adhesive. Thermally conductive adhesive can be implemented as electrically conductive or non-electrically conductive material. LEDs 120-122 are light emitting optoelectronic devices that produce light when power is supplied causing them to forward bias. The light produced may be within the blue, green, red, amber or other portion of the spectrum, depending on the material utilized in manufacturing the LED or method of manufacture, such as, for example color converted LEDs. In one embodiment, one or more LEDs 120-122 are mounted to one or more associated pads 140-142, whereby each LED is mounted to an associated pad. In an example, LEDs 120-122 are implemented as suitable light emitting diodes, such as, for example encapsulated LEDs Luxeon™ Emitter available from Lumiled of San Jose, Calif., USA.

Heatsink 160 functions to conduct and dissipate heat, as well as to provide support to flexible substrate 110. Heatsink 160 is manufactured from conductive material, such as, for example aluminum and copper. Heatsink 160 may be implemented as any suitable heatsink, such as, for example a heat spreader. In one embodiment, the bottom surface of flexible substrate 110 is operably coupled to heatsink 160 by a lamination process.

In operation, flexible substrate 110 provides a path for heat transfer from pads 140-142 to heatsink 160. Thermal build-up within pads 140-142 is transferred to flexible substrate 110 due to physical contact between the two components. The thermal build-up within flexible substrate 110 is then transferred to heatsink 160 due to physical contact between the two components.

FIG. 2 illustrates a cross-sectional side view of LED light source assembly 101. LED light source assembly 101 includes a standard substrate 111, one or more vias 180, light emitting diodes 120-122, trace layers 130-133, pads 140-142, insulation layers 150, heatsink 160, and bonding layer 170. In FIG. 2, like elements described in FIG. 1 that are numbered identically function as described in FIG. 1, above. LED light source assembly 101 may include additional components not relevant to the present discussion.

In FIG. 2, substrate 111 includes two surfaces, a top surface and a bottom surface. One or more vias 180 are disposed through the top surface of substrate 111 to the bottom surface of substrate 111. The top surface of substrate 111 includes trace layers 130-133 overlying the top surface as well as insulation layers 150 overlying the top surface. The top surface of substrate 111 additionally includes pads 140-142 overlying trace layers 130-133 and light emitting diodes 120-122 operably coupled to pads 140-142.

Substrate 111 is a mounting platform that is designed to allow components operably coupled to substrate 111 to function as designed. Substrate 111 can be manufactured as any suitable substrate, such as, for example a printed circuit board (PCB). In an example, substrate 111 is implemented as an FR-4 PCB available from a wide range of manufacturers. In one embodiment, substrate 111 is produced including one or more trace layers 130-133 overlying substrate 111 and one or more pads 140-142 overlying trace layers 130-133.

Vias 180 are thermally conductive pathways that are designed to allow heat to flow from pads 140-142 to heatsink 160. Vias 180 are located such that pads 140-142 are disposed proximate to one end of the vias. Vias 180 are further detailed in FIG. 3, below. In one embodiment, vias 180 are constructed so as to be substantially perpendicular to the top surface and the bottom surface of substrate 111.

Heatsink 160 functions to conduct and dissipate heat, as well as to provide support to multi-layered substrate 112. Bonding layer 170 functions to attach heatsink 160 to the bottom surface of substrate 111. In one embodiment, bonding layer 170 is implemented as a thermally conductive bonding layer, such as, for example a thermally conductive adhesive or a thermally conductive tape.

In operation, vias 180 provide a path for heat transfer from pads 140-142 to heatsink 160. Thermal build-up within pads 140-142 is transferred to vias 180 due to pads 140-142 being disposed proximate to one end of the vias 180. In one embodiment, the thermal build-up within vias 180 is then transferred to heatsink 160 due to physical contact between vias 180 and heatsink 160. In another embodiment, thermal build-up within vias 180 is transferred to bonding layer 170, and is further transferred to heatsink 160 due to physical contact between bonding layer 170 and heatsink 160.

FIG. 3 illustrates a cross-sectional side view detailing via 180 of LED light source assembly 101 of FIG. 2. Via 180 includes channel 181, sidewall 182, heatsink interface 183, and pad interface 184. Substrate 111 and insulation layers 150 are provided for illustrative purposes to define via 180. In FIG. 3, like elements described in FIG. 2 that are numbered identically function as described in FIG. 2, above. Vias 180 may include additional components not relevant to the present discussion.

Via 180 is defined by channel 181 within substrate 111 that is disposed through the top surface of substrate 111 to the bottom surface of substrate 111. In one embodiment, channel 181 is produced by any suitable method during production of the substrate. In another embodiment, channel 181 is produced subsequent to production of the substrate. In an example, via 180 is defined by channel 181 within substrate 111 that is disposed through the top surface of substrate 111 to the bottom surface of substrate 111 having a diameter of 50-600 micro meters (μm).

In another embodiment, via 180 additionally includes sidewall 182 that is disposed through the top surface of substrate 111 to the bottom surface of substrate 111 and further defines via 180. In this embodiment, via 180 also includes heatsink interface 183 and pad interface 184. Heatsink interface 183 is operably coupled to the bonding layer and in thermal communication with the heatsink. Pad interface 184 is operably coupled to the trace layer and in thermal communication with the pad. In one embodiment, sidewall 182 defines channel 181. In this embodiment, heatsink interface 183 is operably coupled to the sidewall 182 and heatsink interface 183 is substantially perpendicular to the sidewall. Pad interface 184 is operably coupled to the sidewall 182 and pad interface 184 is substantially perpendicular to the sidewall.

Sidewall 182, heatsink interface 183, and pad interface 184 provide an additional thermal conduction path for removal of heat from the pads and transfer of the removed heat to the heatsink. Sidewall 182, heatsink interface 183, and pad interface 184 are manufactured from any suitably thermally conductive material, such as, for example copper. In an example, sidewall 182 is a thermally conductive sidewall manufactured from thermally conductive material having a thickness of 10-80 micro meters (μm), heatsink interface 183 is manufactured from thermally conductive material having a thickness of 10-100 micro meters (μm), pad interface 184 is manufactured from thermally conductive material having a thickness of 10-100 micro meters (μm), and channel 181 is disposed through substrate 111 with a diameter of 50-600 micro meters (μm). In an example, heatsink interface 183 and pad interface 184 are manufactured utilizing a process similar to manufacture of the trace and pad layers. In this example, the trace layer is manufactured overlying pad interface 184 and the pad layer is manufactured overlying the trace layer.

In another embodiment, channel 181 further includes a highly conductive material, such as, for example solder mask. The highly conductive material within channel 181 provides an enhanced thermal conduction path for removal of heat from the pads and transfer of the removed heat to the heatsink. In an example, channel 181 further includes a highly conductive process compatible material, such as, commercially available solder.

FIG. 4 illustrates a cross-sectional side view of an LED light source assembly 102. LED light source assembly 102 includes a flexible substrate 110, one or more vias 180, light emitting diodes 120-122, trace layers 130-133, pads 140-142, and heatsink 160. In FIG. 4, like elements described in FIG. 1 that are numbered identically function as described in FIG. 1, above. LED light source assembly 102 may include additional components not relevant to the present discussion.

In FIG. 4, flexible substrate 110 includes two surfaces, a top surface and a bottom surface. One or more vias 180 are disposed through the top surface of substrate 110 to the bottom surface of substrate 110. The top surface of substrate 111 includes trace layers 130-133 overlying the top surface as well as insulation layers 150 overlying the top surface. The top surface of flexible substrate 110 additionally includes pads 140-142 overlying trace layers 130-133 and light emitting diodes 120-122 operably coupled to pads 140-142. The bottom surface of flexible substrate 110 is operably coupled to heatsink 160.

Flexible substrate 110 is a flexible mounting platform that is designed to allow components operably coupled to flexible substrate 110 to function as designed. In one embodiment, flexible substrate 110 is produced including one or more trace layers 130-133 overlying flexible substrate 110, one or more pads 140-142 mounted on the trace layers 130-133, and one or more vias 180. In an example, flexible substrate 110 is produced as a flex tape having a thickness of less than 50 micro meters (μm) with one or more trace layers 130-133 overlying flexible substrate 110, one or more pads 140-142 mounted on the trace layers 130-133, and one or more vias 180 having a diameter of 50-600 micro meters (μm). In another example, the one or more vias 180 having a diameter of 50-600 micro meters (μm) are added to flexible substrate 110 at a later point in the manufacturing process. Flexible substrate 110 can be implemented as any suitable flexible substrate, such as, for example double-layer flex available from COMPASS Technologies Co. Ltd of Shatin, Hong Kong.

Vias 180 are thermally conductive pathways that are designed to allow heat to flow from pads 140-142 to heatsink 160. Vias 180 are located such that pads 140-142 are disposed proximate to one end of the vias. Vias 180 are further detailed in FIG. 3, above. In one embodiment, vias 180 are constructed so as to be substantially perpendicular to the top surface and the bottom surface of substrate 110.

Heatsink 160 functions to conduct and dissipate heat, as well as to provide support to flexible substrate 110. In one embodiment, the bottom surface of flexible substrate 110 is operably coupled to heatsink 160 by a lamination process.

In operation, flexible substrate 110 and vias 180 provide a path for heat transfer from pads 140-142 to heatsink 160. Thermal build-up within pads 140-142 is transferred to flexible substrate 110 and vias 180. Thermal build-up within pads 140-142 is transferred to flexible substrate 110 due to physical contact between the two components. Thermal build-up within pads 140-142 is transferred to vias 180 due to pads 140-142 being disposed proximate to one end of the vias 180. The thermal build-up within flexible substrate 110 and vias 180 is then transferred to heatsink 160 due to physical contact between the two components.

FIG. 5 illustrates a cross-sectional side view of an LED light source assembly 103. LED light source assembly 103 includes a multi-layered substrate 112, one or more vias 180, light emitting diodes 120-122, trace layers 130-133, pads 140-142, heatsink 160, bonding layer 170, and secondary trace layers 190. In FIG. 5, like elements described in FIG. 2 that are numbered identically function as described in FIG. 2, above. LED light source assembly 103 may include additional components not relevant to the present discussion.

Multi-layered substrate 112 includes substrate layers 111 with secondary trace layers 190 interposed between each substrate layer to form multi-layered substrate 112. In one embodiment, secondary trace layers 190 are implemented as copper. Multi-layered substrate 112 additionally includes two outside surfaces, a first outside surface and a second outside surface. One or more vias 180 are disposed through the first outside surface of multi-layered substrate 112 to the second outside surface of multi-layered substrate 112. The top surface of substrate 111 includes trace layers 130-133 overlying the top surface as well as insulation layers 150 overlying the top surface. The top surface of substrate 111 additionally includes pads 140-142 overlying trace layers 130-133 and light emitting diodes 120-122 operably coupled to pads 140-142. The second outside surface of multi-layered substrate 111 is operably coupled to heatsink 160 by bonding layer 170.

Multi-layered substrate 112 is a mounting platform that is designed to allow components operably coupled to multi-layered substrate 112 to function as designed. Multi-layered substrate 112 can be manufactured from any suitable substrate material layers, such as, for example multiple printed circuit board (PCB) layers. In one embodiment, multi-layered substrate 112 is produced from multiple layers of substrate material operably coupled in a vertical stack utilizing a secondary trace layer 190 between each substrate layer 111. In an example, multi-layered substrate 112 is implemented as any commercially available multi-layered substrate available from a wide range of manufacturers, such as, for example SHARP of Osaka, Japan. In one embodiment, multi-layered substrate 112 is produced including one or more trace layers 130-133 overlying the first outside surface of substrate 112, and one or more pads 140-142 mounted on trace layers 130-133. In another embodiment, a layer of thermally conductive material (not shown) is attached to the second outside surface of multi-layered substrate 112.

Vias 180 are thermally conductive pathways that are designed to allow heat to flow from pads 140-142 to heatsink 160. Vias 180 are located such that pads 140-142 are disposed proximate to one end of the vias. Vias 180 are further detailed in FIG. 6, below. Vias 180 are constructed through each substrate layer 111 of multi-layered substrate 112. In one embodiment, vias 180 are constructed so as to be substantially perpendicular to the first outside surface and the second outside surface of multi-layered substrate 112. In other embodiments, secondary trace layers 190 may or may not be in physical contact with vias 180.

Heatsink 160 functions to conduct and dissipate heat, as well as to provide support to multi-layered substrate 112. Bonding layer 170 functions to attach heatsink 160 to the second outside surface of multi-layered substrate 112. In one embodiment, bonding layer 170 is implemented as a thermally conductive bonding layer, such as, for example a thermally conductive adhesive or a thermally conductive tape.

In operation, vias 180 provide a path for heat transfer from pads 140-142 to heatsink 160. Thermal build-up within pads 140-142 is transferred to vias 180 due to pads 140-142 being disposed proximate to one end of the vias 180. In one embodiment, the thermal build-up within vias 180 is then transferred through one or more bonding layers 171 and vias between substrate layers within multi-layered substrate 112. The thermal build-up within vias 180 proximate heatsink 160 is transferred to heatsink 160 due to physical contact between vias 180 and bonding layer 170. The thermal build-up within vias 180 is transferred to bonding layer 170, and is further transferred to heatsink 160 due to physical contact between bonding layer 170 and heatsink 160.

FIG. 6 illustrates a cross-sectional side view detailing via 180 of LED light source assembly 103 of FIG. 5. Via 180 includes channel 181, sidewall 182, heatsink interface 183, and pad interface 184. Substrate 111 is provided for illustrative purposes to define via 180. In FIG. 6, like elements described in FIG. 5 that are numbered identically function as described in FIG. 5, above. Vias 180 may include additional components not relevant to the present discussion.

Via 180 is defined by channel 181 within substrate 111 that is disposed through the top surface of multi-layered substrate 112 to the bottom surface of multi-layered substrate 112. In one embodiment, channel 181 is produced by any suitable method during production of the substrate. In another embodiment, channel 181 is produced subsequent to production of the substrate. In an example, via 180 is defined by channel 181 within multi-layered substrate 112 that is disposed through the top surface of multi-layered substrate 112 to the bottom surface of multi-layered substrate 112 having a diameter of 50-600 micro meters (μm).

In another embodiment, via 180 additionally includes sidewall 182 that is disposed through the top surface of multi-layered substrate 112, through substrate layers 111 and secondary trace layers 190, and to the bottom surface of multi-layered substrate 112. Sidewall 182 further defines via 180. In this embodiment, via 180 also includes heatsink interface 183 and pad interface 184. Heatsink interface 183 is operably coupled to the bonding layer and in thermal communication with the heatsink. Pad interface 184 is operably coupled to the trace layer and in thermal communication with the pad. In one embodiment, sidewall 182 defines channel 181. In this embodiment, heatsink interface 183 is operably coupled to the sidewall 182 and heatsink interface 183 is substantially perpendicular to the sidewall. Pad interface 184 is operably coupled to the sidewall 182 and pad interface 184 is substantially perpendicular to the sidewall.

Sidewall 182, heatsink interface 183, and pad interface 184 provide an additional thermal conduction path for removal of heat from the pads and transfer of the removed heat to the heatsink. Sidewall 182, heatsink interface 183, and pad interface 184 are manufactured from any suitably thermally conductive material, such as, for example copper. In an example, sidewall 182 is a thermally conductive sidewall manufactured from copper having a thickness of 5-50 micro meters (μm), heatsink interface 183 is manufactured from thermally conductive material having a thickness of 10-100 micro meters (μm), pad interface 184 is manufactured from thermally conductive material having a thickness of 10-100 micro meters (μm), and channel 181 is disposed through substrate 111 with a diameter of 50-600 micro meters (μm). In an example, heatsink interface 183 and pad interface 184 are manufactured utilizing a process similar to manufacture of the trace and pad layers. In this example, the trace layer is manufactured overlying pad interface 184 and the pad layer is manufactured overlying the trace layer.

In another embodiment, channel 181 either includes a highly conductive material. The highly conductive material within channel 181 provides an enhanced thermal conduction path for removal of heat from the pads and transfer of the removed heat to the heatsink. In an example, channel 181 further includes a highly conductive process compatible material, such as, commercially available solder.

FIG. 7 illustrates a method 700 for fabricating a device for thermal management of an LED. Method 700 may utilize one or more concepts detailed in FIGS. 1-6, above. Method 700 begins at block 710.

At block 720, a flexible substrate is provided. In one embodiment, the flexible substrate includes one or more trace and insulation layers, and additionally includes one or more pads attached to the trace layers. In an example and referring to FIG. 1 above, flexible substrate 110 including trace layers 130-133, pads 140-142, and insulation layers 150 is provided. In another example and referring to FIG. 4 above, flexible substrate 110 including trace layers 130-133, pads 140-142, insulation layers 150, and vias 180 is provided.

At block 730, the flexible substrate is attached to a heatsink. The flexible substrate is attached to the heatsink by any commercially available method, such as, for example by lamination. In an example and referring to FIG. 1 above, flexible substrate 110 is attached to heatsink 160 utilizing a lamination methodology.

At block 740, LEDs are attached to the flexible substrate. In one embodiment, LEDs are attached to the flexible substrate by any commercially available method, such as, for example as described in FIG. 1 above. At block 750, method 700 terminates.

FIG. 8 illustrates a method 800 for fabricating a device for thermal management of an LED. Method 800 may utilize one or more concepts detailed in FIGS. 1-6, above. Method 800 begins at block 810.

At block 820, a substrate including vias is provided. In one embodiment, the substrate includes one or more trace and insulation layers, and additionally includes one or more pads attached to the trace layers. In an example and referring to FIG. 2 above, substrate 111 including trace layers 130-133, pads 140-142, insulation layers 150, and vias 180 is provided. In another example and referring to FIG. 5 above, multi-layered substrate 112 including trace layers 130-133, pads 140-142, insulation layers 150, and vias 180 is provided.

At block 830, LEDs are attached to the substrate. In one embodiment, LEDs are attached to the substrate by any commercially available method, such as, for example as described in FIG. 2 above.

At block 840, the substrate is attached to a heatsink. The substrate is attached to the heatsink by any commercially available method, such as, for example by utilizing a bonding layer. In an example and referring to FIG. 2, substrate 111 attached to heatsink 160 utilizing bonding layer 170. At block 850, method 800 terminates.

FIG. 9 illustrates a method 900 for fabricating a device for thermal management of an LED. Method 900 may utilize one or more concepts detailed in FIGS. 1-6, above. Method 900 begins at block 910.

At block 920, a substrate including vias is provided. In one embodiment, the substrate includes one or more trace and insulation layers, and additionally includes one or more pads attached to the trace layers. In an example and referring to FIG. 2 above, substrate 111 including trace layers 130-133, pads 140-142, insulation layers 150, and vias 180 is provided. In another example and referring to FIG. 5 above, multi-layered substrate 112 including trace layers 130-133, pads 140-142, insulation layers 150, and vias 180 is provided.

At block 930, the substrate is attached to a heatsink. The substrate is attached to the heatsink by any commercially available method, such as, for example by utilizing a bonding layer. In an example and referring to FIG. 2, substrate 111 is attached to heatsink 160 utilizing bonding layer 170.

At block 940, LEDs are attached to the substrate. In one embodiment, LEDs are attached to the substrate by any commercially available method, such as, for example, as described in FIG. 2 above. At block 950, method 900 terminates.

The above-described device and method for providing thermal management of an LED light source are example device and implementations. These methods and implementations illustrate one possible approach for providing thermal management of an LED light source. The actual implementation may vary from the method discussed. Moreover, various other improvements and modifications to this invention may occur to those skilled in the art, and those improvements and modifications will fall within the scope of this invention as set forth in the claims below.

The present invention may be embodied in other specific forms without departing from its essential characteristics. The described embodiments are to be considered in all respects only as illustrative and not restrictive.

1. A device 101 for thermal management of an LED 120, said device comprising:
a heatsink 160;
a substrate 111 overlying said heatsink 160;
a trace layer 130 overlying said substrate 110; and
a via 180 extending through said substrate 111, wherein said via 180 is in thermal communication with said trace layer 130 and said heatsink 160 to transfer to said heatsink 160 at least a portion of any heat applied to said trace layer 130 by said LED 120.

2. The device of claim 1, further comprising:
a bonding layer 170 between said substrate 110 and said via 180.

3. The device of claim 2, wherein said bonding layer 170 is a thermally conductive adhesive.

4. The device of claim 2, wherein said bonding layer 170 is a thermally conductive tape.

5. The device of claim 1, wherein said substrate 111 is a multi-layered substrate 112.

6. The device of claim 1, wherein said substrate 111 is a printed circuit board.

7. The device of claim 1, wherein said substrate 111 is a flexible substrate.

8. The device of claim 1, wherein said via 180 includes:
a sidewall 182 defining a channel 181 through said substrate 110, said channel 181 interfacing with said trace layer 130 to thereby establish the thermal communication between said via 180 and said trace layer 130.

9. The device of claim 8, further comprising:
a thermal conductive material filling at least a portion of said channel 181.

10. The device of claim 1, wherein said via 180 includes:
a sidewall 182 defining a channel 181 through said substrate 110, said channel 181 interfacing with said heat sink 180 to thereby establish the thermal communication between said via 180 and said heat sink 180.

11. The device of claim 10, further comprising:
a thermal conductive material filling at least a portion of said channel 181.

12. A device 101 for thermal management of an LED 120, said device comprising:
a heatsink 160;
a trace layer 130; and
a flexible substrate 111 in thermal communication with said trace layer 130 and said heatsink 160 to transfer to said heatsink 160 any heat applied to said trace layer 130 by said LED 120.

13. The device of claim 12, further comprising:
a via 180 extending through said substrate 111, wherein said via 180 is in thermal communication with said trace layer 130 and said heatsink 160 to enhance the transfer to said heatsink 160 of any heat applied to said trace layer 130 by said LED 120.

14. The device of claim 13, wherein said via 180 includes:
a sidewall 182 defining a channel 181 through said substrate 110, said channel 181 interfacing with said trace layer 130 to thereby establish the thermal communication between said via 180 and said trace layer 130.

15. The device of claim 14, further comprising:
a thermal conductive material filling at least a portion of said channel 181.

16. The device of claim 13, wherein said via 180 includes:
a sidewall 182 defining a channel 181 through said substrate 110, said channel 181 interfacing with said heat sink 180 to thereby establish the thermal communication between said via 180 and said heat sink 180.

17. The device of claim 16, further comprising:
a thermal conductive material filling at least a portion of said channel 181.

18. A device 101 for thermal management of an LED 120, said device comprising:
a heatsink 160;
a substrate 111 overlying said heatsink 160;
a trace layer 130 overlying said substrate 110; and
a via 180 including a sidewall 182 defining a channel 181 extending through said substrate 110, wherein said channel 181 is beneath said trace layer 130 and above said heatsink 160 to transfer any heat applied to said trace layer 130 by said LED 120 to said heatsink 160.

19. The device of claim 18, further comprising:
a thermal conductive material filling at least a portion of said channel 181.

20. The device of claim 18, further comprising:
a bonding layer 170 between said substrate 110 and said via 180.
